(19) United States
(12) Patent Application Publication
(10) Pub. No.: US 2016/0143145 A1
(43) Pub. Date: May 19, 2016

(54) ELECTRICAL DEVICE

(71) Applicant: E I DU PONT DE NEMOURS AND COMPANY, Wilmington, DE (US)

(72) Inventors: AKIRA INABA, KAWASAKI-SHI (JP); SATOMI YAMASHITA, Kawasaki-shi (JP)

(21) Appl. No.: 14/540,285

(22) Filed: Nov. 13, 2014

(51) Int. Cl. H05K 1/18; H05K 3/34; H05K 3/30; H05K 1/03; H05K 1/09

(52) U.S. Cl. CPC H05K 1/181; H05K 1/0306; H05K 1/09; H05K 3/305; H05K 3/3457; H05K 2201/10015; H05K 2201/10022; H05K 2201/1003

(57) ABSTRACT

An electrical device comprising: a substrate; an electrical circuit formed on the substrate; an electrical component mounted on the substrate; solder physically and electrically joining the electrical circuit and the electrical component; wherein the electrical component comprises an outer electrode comprising (i) 100 parts by weight of a conductive powder comprising a copper-nickel-zinc (Cu—Ni—Zn) alloy powder, and (ii) 1 to 40 parts by weight of an organic polymer.

### FIELD OF INVENTION

The present invention relates to an electrical device and a method of manufacturing it.

### TECHNICAL BACKGROUND OF THE INVENTION

An electrical device contains an electric component that is joined to an electrical circuit by a solder. An electric component needs good solderability and solder leach resistance. “Solderability” here refers to the ease with which a soldered joint can be made to that material. An electrode of good solderability wets well with solder to make a good solder joint with another material. “Solder leach resistance” here refers to a tolerance for solder draining an electrode of metal.

EP0720187 discloses a multiple-layered capacitor having a terminal electrode that is made of a composition containing a silver particles and a glass frit.

### BRIEF SUMMARY OF THE INVENTION

An objective is to provide an electrical device containing an outer electrode having a sufficient soldering property.

An aspect of the invention relates to an electrical device comprising: a substrate; an electrical circuit formed on the substrate; an electrical component mounted on the substrate; solder physically and electrically joining the electrical circuit and the electrical component; wherein the electrical component comprises an outer electrode comprising (i) 100 parts by weight of a conductive powder comprising a copper-nickel-zinc (Cu—Ni—Zn) alloy powder, and (ii) 1 to 40 parts by weight of an organic polymer.

Another aspect of the invention relates to a method of manufacturing an electrical device comprising the steps of: providing a substrate; forming an electrical circuit on the substrate; mounting an electrical component on the substrate; and physically and electrically joining the electrical circuit and the electrical component by use of a solder; wherein the electrical component comprises an outer electrode comprising (i) 100 parts by weight of a conductive powder comprising a Cu—Ni—Zn alloy powder, and (ii) 1 to 40 parts by weight of an organic polymer.

An electrical device that has a sufficient soldering property can be provided by the present invention.

### BRIEF DESCRIPTION OF THE DRAWINGS

FIG. 1 is schematic cross-sectional drawings for explaining the structure of the electrical device.

FIG. 2 is a cross sectional diagram of a Cu—Ni—Zn alloy powder that is coated with silver.

### DETAILED DESCRIPTION OF THE INVENTION

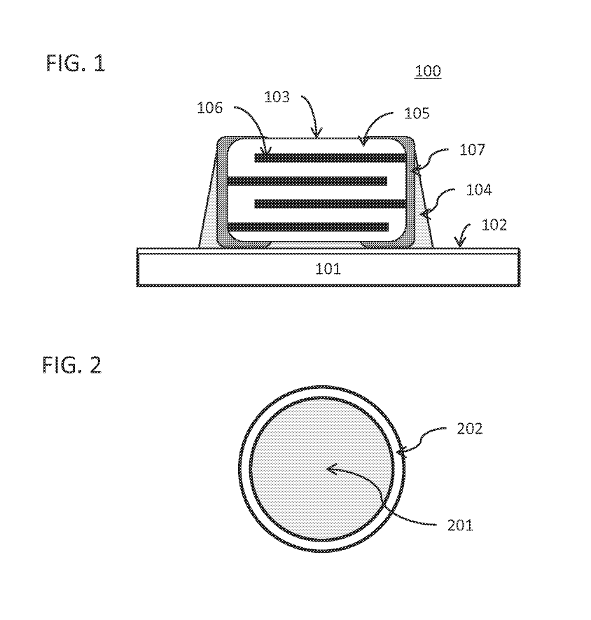

The electrical device and the method of manufacturing the electrical device are explained below along with FIG. 1.

### Electrical Device

A substrate 101 is provided. There is no restriction on the type of the substrate 101. The substrate 101 can be rigid or flexible. The substrate can be a paper phenol substrate, a paper epoxy substrate, a glass epoxy substrate, a ceramic substrate, a low temperature co-fired ceramic (LTCC) substrate, a polymer film, a glass substrate, a ceramic substrate or a combination thereof in an embodiment.

The electrical circuit 102 is formed on the substrate 101. The circuit 102 is an electrical interconnection of electrical elements such as an electrical component, voltage sources, current sources and switches on the substrate 101. The electrical circuit 102 comprises metal such as copper, silver or gold in an embodiment.

The electrical circuit 102 can be formed with a thick-film paste comprising an electrical conductive material. The thick-film paste can be screen printed on the substrate 101 in a desired pattern and cured by heat in an embodiment. A copper-clad laminate (CCL) that contains an insulating layer and a copper foil is used to form the electrical circuit 102 on the substrate 101. A resist is placed over the copper foil and selectively removed. The remaining resist protects the copper foil. Subsequent etching removes the unwanted copper and the remaining copper is a desired circuit pattern.

A capacitor 103, i.e., an electric component is mounted on the electrical circuit 102. The electrical component 103 comprises an outer electrode 107.

The capacitor 103 has a laminated ceramic 105, an internal electrode 106 and outer electrodes 107. The internal electrode 106 is between the ceramic layers. The outer electrode 107 is formed on both sides of the laminated ceramic 105 and contacts with the internal electrode 106.

The outer electrode 107 comprises (i) 100 parts by weight of a conductive powder comprising a Cu—Ni—Zn alloy powder, and (ii) 1 to 40 parts by weight of an organic polymer.

The Cu—Ni—Zn alloy powder comprises at least copper, nickel and zinc.

Copper in the Cu—Ni—Zn alloy powder is 60 to 96 weight percent (wt. %) in an embodiment, 65 to 90 wt. % in another embodiment, 70 to 89 wt. % in another embodiment, 75 to 88 wt. % in another embodiment, and 78 to 85 wt. % in still another embodiment based on the weight of the Cu—Ni—Zn alloy powder.

Nickel in the Cu—Ni—Zn alloy powder is 1 to 30 wt. % in an embodiment, 2 to 28 wt. % in another embodiment, 4 to 26 wt. % in another embodiment, 6 to 26 wt. % in another embodiment, and 8 to 20 wt. % in still another embodiment based on the weight of the Cu—Ni—Zn alloy powder.

Zinc in the Cu—Ni—Zn alloy powder is 3 to 12 wt. % in an embodiment, 4 to 11 wt. % in another embodiment, 5 to 10 wt. % in another embodiment, and 6 to 9 wt. % in still another embodiment based on the weight of the Cu—Ni—Zn alloy powder.

The Cu—Ni—Zn alloy powder can further comprise other metals such as silver (Ag), aluminum (Al), tin (Sn), bismuth (Bi), phosphate (P) and a mixture thereof in an embodiment.

The conductive powder can comprise other metal powder such as Cu element powder, silver (Ag) element powder, aluminum (Al) element powder, nickel (Ni) element powder, zinc (Zn) element powder, tin (Sn) element powder, bismuth (Bi) element powder, phosphate (P) element powder and a mixture thereof in another embodiment.

The Cu—Ni—Zn alloy powder is 50 to 100 wt. % in an embodiment, 60 to 100 wt. % in another embodiment, 70 to 100 wt. % in another embodiment, 80 to 100 wt. % in another embodiment, 90 to 100 wt. % in another embodiment, 95 to 100 wt. % in another embodiment based on the weight of the conductive powder.

The Cu—Ni—Zn alloy powder 201 can be coated with silver (Ag) 202 on its surface in another embodiment as shown in FIG. 2. Weight ratio of the coating Ag 202 and the Cu—Ni—Zn alloy powder 201 (Ag:Cu—Ni—Zn alloy) is 5:95 to 50:50 in an embodiment, 7:93 to 40:60 in another embodiment, 8:92 to 35:65 in another embodiment, and 9:91 to 25:75 in still another embodiment. The Cu—Ni—Zn alloy powder coating with silver as stock of material can be preserved with less oxidation.

There is no limitation on shape of the conductive powder. A flaky conductive powder, spherical conductive powder or a mixture thereof are often purchasable in the market.

The particle diameter (D50) of the conductive powder can be 0.5 to 20 μm in an embodiment, 0.8 to 15 μm in another embodiment, 1.0 to 10 μm in another embodiment, 1.2 to 5 μm in another embodiment, 1.5 to 3 μm in another embodiment. The conductive powder with such particle size can disperse well in the organic vehicle. The average diameter (D50) is obtained by measuring the distribution of the powder diameters by using a laser diffraction scattering method with Microtrac model X-100.

The outer electrode 107 is made of a thermosetting conductive paste in an embodiment. The thermosetting conductive paste is applied onto the both sides of the laminated ceramic 105 in an embodiment. The thermosetting conductive paste can be applied on the laminated ceramic 105 screen printing, dipping or transfer printing in another embodiment.

The viscosity of the thermosetting conductive paste is between 30 to 500 Pa·s measured by Brookfield HBT with a spindle #14 at 10 rpm in an embodiment. In the event of screen printing, the viscosity of the conductive paste can be 60 to 200 Pa·s.

A wide variety of inert viscous materials can be used as the organic polymer. The organic polymer can comprise a thermosetting polymer in an embodiment. The thermosetting polymer can be 90 to 100 wt. % based on weight of the organic polymer.

The thermosetting polymer can be selected from the group consisting of phenolic resin, urea resin, melamine resin, epoxy resin, unsaturated polyester resin, silicone resin, polyurethane resin, polyvinyl butyral resin, polyimide resin, acrylic resin and a mixture thereof in an embodiment.

The thermosetting polymer can be selected from the group consisting of phenolic resin, melamine resin, polyurethane resin and a mixture thereof in another embodiment.

The thermosetting polymer can comprise phenolic resin in another embodiment. Phenolic resin has more heat resistance at soldering temperature such as 240 to 270° C.

The organic polymer further contains thermoplastic polymer such as ethyl cellulose, ethylhydroxyethyl cellulose, wood rosin, phenoxy resin, polyamide resin, polyester resin, polyacetal resin and a mixture thereof in another embodiment.

The applied conductive paste is heated at 100 to 300° C. in an embodiment thereby the thermosetting conductive paste is cured to become the outer electrode 107. The heating temperature can be 120 to 250° C. in another embodiment, 150 to 220° C. in another embodiment. The heating time can be 10 to 90 minutes in an embodiment, 15 to 70 minutes in another embodiment, and 20 to 45 minutes in another embodiment. The heating temperature is adjustable in consideration of the heating time such as low temperature for long time and high temperature for short time.

The electrical component can be a chip resistor, a capacitor, an inductor or a semiconductor chip in another embodiment.

The capacitor 103 and the electrical circuit 102 are physically and electrically joined with a solder 104. The solder 104 melts to flow and join the outer electrode 107 of the capacitor 103 and the electrical circuit 102.

The solder 104 comprise a metal selected from the group consisting of tin (Sn), lead (Pb), silver (Ag), copper (Cu), zinc (Zn), bismuth (Bi), indium (In), aluminum (Al) and a combination thereof in an embodiment.

The solder is a lead-free in another embodiment. The lead-free solder comprise metals selected from the group consisting of tin (Sn), silver (Ag), copper (Cu), zinc (Zn), bismuth (Bi), indium (In), aluminum (Al) and a combination thereof in another embodiment. The lead-free solder can be selected from Sn/Ag/Cu, Sn/Zn/Bi, Sn/Cu, Sn/Ag/In/Bi or Sn/Zn/Al in another embodiment.

Lead-free solder is environment-friendly, however lead-free solder often causes less solderability and solder leach resistance than lead-containing solder. The electrical device of the present invention could have less electrically problem because the outer-electrode 107 of the electrical component has sufficient solderability and solder leach resistance against lead-free solder as well as lead-containing solder.

The solder is purchasable in the market, for example Eco Solder® from Senju Metal Industry Co., Ltd., Evasol® from Ishikawa Metal Co., LTD. and Fine Solder® from Matsuo Handa CO., LTD.

In an embodiment, a solder paste is used to joint the electric component 103 and the circuit 102. A solder paste is printed on the circuit 102 and the electric component 103 is placed on the printed solder paste followed by reflow process. During the reflow, the substrate having the electric component 103 and the applied solder paste is subjected to controlled heat that melts the solder to connect the joint.

The outer electrode 107 can be plated with a metal such as nickel and then soldered over the plating in another embodiment. The plating could further enhance the solderability and solder leach resistance of the electrode. The electrode can be directly soldered without plating in another embodiment.

### Thermosetting Conductive Paste

The thermosetting conductive paste to form the outer electrode is explained in detail below.

The thermosetting conductive paste contains at least the Cu—Ni—Zn alloy powder as a conductive powder dispersed in an organic vehicle.

The Cu—Ni—Zn alloy powder is obtainable by any general method of making alloy powder. Mechanical alloy method, chemical vapor deposition method and atomization method that are well known can be raised as an example.

Mechanical alloy method: A mixture of copper powder, nickel powder and zinc powder at a particular weight ratio is mixed in a ball mill thereby the powders are repeatedly press-bonded and grinded to be a Cu—Ni—Zn alloy powder.

Chemical vapor deposition method: A microreactor is charged with a mixture of a copper salt such as Cu(NO₃)₂ and CuSO₄, a nickel salt such as Ni(NO₃)₂ and NiSO₄ and a zinc salt such as Zn(NO₃)₂ and ZnSO₄. The mixture is heated in a nitrogen atmosphere to gasify. The gas of the metal salts is reacted with hydrogen (H₂) to get the metal salts reduced. The reduced metals clump together to form the Cu—Ni—Zn alloy powder.

Atomization method: A bath is charged with Cu particles, Ni particles and Zn particles and heated to melt the metal particles. The homogenous molten metal is transferred to a reservoir to supply a constant flow of metal into the atomizing chamber. The metal stream that enters the chamber is struck by a high velocity stream of the atomizing medium such as water, air, and an inert gas. The metal stream is disintegrated into fine droplets which solidify during their fall through the atomizing chamber. Particles are collected at the bottom of the chamber.

In an embodiment, the Cu—Ni—Zn alloy powder is manufactured by the atomization method.

The Cu, Ni and Zn amounts in the Cu—Ni—Zn alloy powder can be adjustable with the material's amount. For example, 80 parts by weight of Cu ingot, 12 parts by weight of Ni ingot and 8 parts by weight of Zn ingot were uses as the materials to make the alloy powder consisting of 80 wt. % of Cu, 12 wt. % of Ni and 8 wt. % of Zn. The powder is then sifted to take out the powder having desired particle diameter.

The Cu—Ni—Zn alloy powder can be coated with silver by the following method. The Cu—Ni—Zn alloy powder and ion-exchanged water of 40° C. are mixed in a container. Silver nitrate, ammonium carbonate as a pH adjuster and ion-exchanged water are mixed in another container. The silver nitrate solution is gradually added to the Cu—Ni—Zn alloy powder water solution and mixed for an hour to precipitate silver on the Cu—Ni—Zn alloy powder surface followed by addition of 14.5% of ethylenediaminetetraacetic acid solution. The Cu—Ni—Zn alloy powder is taken out after about fifteen minutes mixing. The silver coated Cu—Ni—Zn alloy powder comes out after washing off the alloy powder with ion-exchanged water and drying at 100° C. for five hours.

The organic vehicle comprises an organic polymer and optionally a solvent. The organic polymer is cured during heating to bind the conductive powder.

The organic polymer in the conductive paste is 1 to 40 parts by weight against 100 parts by weight of the conductive powder. The organic polymer is 3 to 30 parts by weight in another embodiment, 5 to 21 parts by weight in another embodiment, 5 to 15 parts by weight in another embodiment against 100 parts by weight of the conductive powder.

The organic polymer can comprise the thermosetting polymer as described above so that the conductive paste is cured at 100 to 300° C. to be an electrode.

The thermosetting polymer can be selected from the group consisting of phenolic resin, urea resin, melamine resin, epoxy resin, unsaturated polyester resin, silicone resin, polyurethane resin, polyvinyl butyral resin, polyimide resin, acrylic resin and a mixture thereof in an embodiment.

The thermosetting polymer can be selected from the group consisting of phenolic resin, melamine resin, polyurethane resin and a mixture thereof in another embodiment.

The thermosetting polymer is 20 to 100 wt. % in an embodiment, 25 to 80 wt. % in another embodiment, 30 to 70 wt. % in an embodiment, 40 to 60 wt. % in an embodiment based on weight of the organic vehicle.

The organic vehicle optionally comprises a solvent in another embodiment. Solvent can be used to adjust the viscosity of the conductive paste to be preferable for applying onto the substrate. The solvent evaporates during heating. The solvent can be selected from the group consisting of texanol, terpineol, carbitol acetate, ethylene glycol, dibuthyl acetate and a mixture thereof in another embodiment.

The organic vehicle is 5 to 50 parts by weight in another embodiment, 10 to 38 parts by weight in another embodiment, 12 to 26 parts by weight in another embodiment against 100 parts by weight of the conductive powder.

An additive such as a surfactant, a dispersing agent, a stabilizer and a plasticizer or an inorganic additive such as metal oxide powder can be added to the conductive paste based on a desired property of the formed electrode.

### Example

The present invention is illustrated by, but is not limited to, the following examples.

### Paste Preparation

The paste materials were prepared as follows.

Conductive powder: A spherical Cu—Ni—Zn alloy powder coated with a silver layer. Contents of Cu, Ni and Zn are shown in Table 1. Weight ratio of the coating Ag and Cu—Ni—Zn alloy (Ag:Cu—Ni—Zn alloy) was 17:83. The particle diameter (D50) was 2 μm.

Organic polymer: A phenolic resin.

Solvent: A mixture of ethylene glycol and dibuthyl acetate.

Additive: A surfactant.

100 parts by weight of the conductive powder, 9.6 parts by weight of the organic polymer, 8 parts by weight of the solvent and 0.5 parts by weight of the additive were mixed well in a mixer followed by a three-roll mill.

### Manufacturing an Electrode

The conductive paste was screen printed onto an alumina substrate (25.4 mm square, 0.6 mm thick). The printed pattern typically had 10 mm wide, 25 mm long and 33 μm thick.

The electrode was formed by heating the printed conductive paste at 170° C. for 30 minutes in a constant temperature oven (DN-42, Yamato Scientific Co., Ltd.). The thermosetting polymer in the paste was cured and the solvent was evaporated during heating.

### Measurement of Solderability

The solderability of the electrode was observed.

A Pb-free solder paste (Sn/Ag/Cu=96.5/3/0.5, M705, Senju Metal Industry Co., Ltd.) was printed directly onto the electrode. The solder paste pattern was circule of 6 mm diameter (28.3 mm²) and 250 μm thick. The alumina substrate with the electrode and the solder paste was placed on a hot-plate to be heated at 260° C. for 10 seconds.

The melted solder paste clumped by its surface tension as the electrode had less solderability. The melted solder paste clumped less and stayed as the electrode had solderability. The better solderability the electrode has, the more the solder spread out to adhere to a larger area of the electrode surface.

The melted solder area was observed with top view by a microscope to evaluate solderability. The solder area ratio that was the melting solder area out of the printed solder paste area before heating [“Solder area ratio (%)”=“Melted solder area”/“Printed solder paste area”×100] was visually measured. The judgment was “Excellent” when solder area ratio was more than 90%, “Good” for around 60 to 90%, “Poor” for less than 60%.

### Measurement of Solder Leach Resistance

The solder leach resistance of the electrode was observed.

The electrode was formed in the same manner as above except for the electrode size. The electrode was 2 mm wide, 25 mm long and 33 μm thick.

The electrode on the alumina substrate was dipped into a 260° C. solder bath filled with the Pb-free solder paste (Eco Solder® M705, Senju Metal Industry Co., Ltd.) for 30 seconds.

After the electrode was removed from the solder bath, it was observed with a top view by a microscope. The electrode surface on which the conductive powder was present, without being leached out in the solder bath, was covered with the solder.

To evaluate solder leach resistance, the solder area ratio was visually measured as the solder area out of the electrode surface area [“Solder area ratio (%)”=“Solder area”/“Electrode surface area”×100].

The judgment was “Excellent” when soldering area was more than 70%, “Good” for 40 to 70%, “Poor” for less than 40%.

### Result

Both solderability and solder leach resistance were improved in Example 1 where the electrode contained Cu—Ni—Zn alloy powder. The electrode had poor solderability and/or solder leach resistance in Comparative (Com.) Example 1 to 3 where the conductive powder lacked Ni, Zn or both.

TABLE 1

| | | Com. | Com. | Com. | |
|---|---|---|---|---|---|
| | | Example 1 | Example 2 | Example 3 | Example 1 |
| Metal weight ratio | Cu | 100 | 92 | 97 | 85 |
| of Cu—Ni—Zn | Ni | 0 | 8 | 0 | 8 |
| alloy (wt. %) | Zn | 0 | 0 | 3 | 7 |

| | | | | |
|---|---|---|---|---|
| Solderability | Poor | Good | Poor | Excellent |
| Solder leach resistance | Poor | Poor | Poor | Good |

Next, the weight ratio of Cu, Ni and Zn of the Cu—Ni—Zn alloy was examined. The electrode was formed in the same manner as Example 1 above except for using different Cu—Ni—Zn alloy powder. The conductive powder here had particle diameter (D50) of 5 μm. Weight ratio of the coating Ag and Cu—Ni—Zn alloy (Ag:Cu—Ni—Zn alloy) was 10:90. Contents of Cu, Ni and Zn are shown in Table 2.

Solderability and solder leach resistance were measured by the same way in Example 1.

Both solderability and solder leach resistance were improved in all examples regardless of the weight ratio of Cu, Ni and Zn. Especially solderability was excellent in Example (Ex.) 3 and 4 and solder leach resistance was excellent in Example 4 to 7.

TABLE 2

| Composition | | Ex. 2 | Ex. 3 | Ex. 4 | Ex. 5 | Ex. 6 | Ex. 7 |
|---|---|---|---|---|---|---|---|
| Metal weight | Cu | 88 | 83 | 80 | 77 | 72 | 67 |
| ratio of | Ni | 4 | 9 | 12 | 15 | 20 | 25 |
| Cu—Ni—Zn | Zn | 8 | 8 | 8 | 8 | 8 | 8 |
| alloy | | | | | | | |

| | | | | | | |
|---|---|---|---|---|---|---|
| Solderability | Good | Excel- | Excel- | Good | Good | Good |
| | | lent | lent | | | |
| Solder Leach | Good | Good | Excel- | Excel- | Excel- | Excel- |
| Resistance | | | lent | lent | lent | lent |

What is claimed is:

1. An electrical device comprising:
a substrate;
a circuit formed on the substrate;
an electric component mounted on the substrate;
a solder physically and electrically jointing the electric circuit and the electric component;
wherein the electric component comprises an outer electrode comprising (i) 100 parts by weight of a conductive powder comprising a copper-nickel-zinc (Cu—Ni—Zn) alloy powder, and (ii) 1 to 40 parts by weight of an organic polymer.

2. The electrical device of claim 1, wherein the substrate is a polymer film, a glass substrate, a ceramic substrate or a combination thereof.

3. The electrical device of claim 1, wherein the circuit comprises copper or silver.

4. The electrical device of claim 1, wherein the electric component is a chip resistor, a capacitor, an inductor or a semiconductor chip.

5. The electrical device of claim 1, wherein the solder is a lead-free solder.

6. The electrical device of claim 5, wherein the lead-free solder comprise metals selected from the group consisting of tin (Sn), silver (Ag), copper (Cu), zinc (Zn), bismuth (Bi), indium (In), aluminum (Al) and a combination thereof.

7. The electrical device of claim 5, wherein the lead-free solder is selected from Sn/Ag/Cu, Sn/Zn/Bi, Sn/Cu, Sn/Ag/In/Bi and Sn/Zn/Al.

8. The electrical device of claim 1, wherein the Cu—Ni—Zn alloy powder contains 60 to 96 weight percent (wt. %) of copper, 1 to 30 wt. % of nickel and 3 to 12 wt. % of zinc based on the weight of the Cu—Ni—Zn alloy powder.

9. The electrical device of claim 1, wherein the Cu—Ni—Zn alloy powder is coated with silver (Ag).

10. The electrical device of claim 9, wherein weight ratio of Ag and the Cu—Ni—Zn alloy powder (Ag:Cu—Ni—Zn alloy) is 5:95 to 50:50.

11. The electrical device of claim 1, wherein particle size (D50) of the conductive powder is 0.5 to 20 μm.

12. The electrical device of claim 1, wherein the Cu—Ni—Zn alloy powder is 50 to 100 wt. % based on weight of the conductive powder.

13. The electrical device of claim 1, wherein the thermosetting polymer is selected from the group consisting of phenolic resin, urea resin, melamine resin, epoxy resin, unsaturated polyester resin, silicone resin, polyurethane resin, polyvinyl butyral resin, polyimide resin, acrylic resin and a mixture thereof.

14. The electrical device of claim 1, wherein the electric component further comprises a plating layer on the outer electrode and wherein the electric component and the circuit is electrically connected via the plating layer.

15. A method of manufacturing an electrical device comprising the steps of:
preparing a substrate;
forming a circuit the substrate;
mounting an electric component on the substrate; and
physically and electrically jointing the electric circuit and the electric component by use of a solder;
wherein the electric component comprises an outer electrode comprising (i) 100 parts by weight of a conductive powder comprising a copper-nickel-zinc (Cu—Ni—Zn) alloy powder, and (ii) 1 to 40 parts by weight of an organic polymer.

16. A method of claim 15, wherein the electric component is a chip resistor, a capacitor, an inductor or a semiconductor chip.

17. A method of claim 15, wherein the solder is a lead-free solder.

18. A method of claim 15, wherein the Cu—Ni—Zn alloy powder contains 60 to 96 weight percent (wt. %) of copper, 1 to 30 wt. % of nickel and 3 to 12 wt. % of zinc based on the weight of the Cu—Ni—Zn alloy powder.

19. A method of claim 15, wherein the thermosetting polymer is selected from the group consisting of phenolic resin, urea resin, melamine resin, epoxy resin, unsaturated polyester resin, silicone resin, polyurethane resin, polyvinyl butyral resin, polyimide resin, acrylic resin and a mixture thereof.

20. An electrical device comprising:
a substrate;
a circuit formed on the substrate;
an electric component mounted on the substrate, wherein the electric component is selected from the group consisting of a chip resistor, a capacitor, an inductor and a semiconductor chip;
a solder physically and electrically jointing the electric circuit and the electric component, wherein the lead-free solder is selected from Sn/Ag/Cu, Sn/Zn/Bi, Sn/Cu, Sn/Ag/In/Bi and Sn/Zn/Al;
wherein the electric component comprises an outer electrode comprising:
(i) 100 parts by weight of a conductive powder comprising a copper-nickel-zinc (Cu—Ni—Zn) alloy powder, wherein the Cu—Ni—Zn alloy powder contains 60 to 96 weight percent (wt. %) of copper, 1 to 30 wt. % of nickel and 3 to 12 wt. % of zinc based on the weight of the Cu—Ni—Zn alloy powder and wherein the Cu—Ni—Zn alloy powder is 50 to 100 wt. % based on weight of the conductive powder, and
(ii) 1 to 40 parts by weight of an organic polymer selected from the group consisting of phenolic resin, urea resin, melamine resin, epoxy resin, unsaturated polyester resin, silicone resin, polyurethane resin, polyvinyl butyral resin, polyimide resin, acrylic resin and a mixture thereof.
